(19) United States
(12) Patent Application Publication
(10) Pub. No.: US 2025/0378253 A1
(43) Pub. Date: Dec. 11, 2025

(54) SYSTEM AND METHOD FOR POST-SILICON ANALOG DESIGN VERIFICATION AND VALIDATION

(71) Applicant: Battelle Memorial Institute, Columbus, OH (US)

(72) Inventors: Vince A Mckinsey, Hilliard, OH (US); Benjamin A. Hayden, Columbus, OH (US); Andrew S Elliott, Sunbury, OH (US); Yaser Hamdy Helal, Columbus, OH (US); Adam Gakuto Kimura, Lewis Center, OH (US)

(21) Appl. No.: 19/227,854

(22) Filed: Jun. 4, 2025

Related U.S. Application Data
(60) Provisional application No. 63/658,025, filed on Jun. 10, 2024.

(51) Int. Cl. G06F 30/367; G06F 30/392

(52) U.S. Cl. CPC G06F 30/367; G06F 30/392

(57) ABSTRACT

In an approach to post-silicon analog design verification and validation, a method includes receiving a recovered layout and a golden data for a design; extracting a recovered netlist from the recovered layout and a golden netlist from the golden data; converting the recovered netlist into a recovered graph and the golden netlist into a golden graph; partitioning the recovered graph and the golden graph; and determining an assurance metric by comparing the recovered graph and the golden graph.

### CROSS-REFERENCE TO RELATED APPLICATIONS

The present application claims the benefit of the filing date of U.S. Provisional Application Ser. No. 63/658,025, filed Jun. 10, 2024, the entire teachings of which application is hereby incorporated herein by reference.

### STATEMENT REGARDING FEDERALLY SPONSORED RESEARCH OR DEVELOPMENT

This invention was made with government support under contract number FA8650-23-C-1000 awarded by the Air Force Research Laboratory. The government has certain rights in the invention.

### TECHNICAL FIELD

The present application relates generally to integrated circuit verification and, more particularly, to post-silicon analog design verification and validation.

### BACKGROUND

Over the last few decades, global economics and market trends within the semiconductor industry have driven modern microelectronics to offshore and untrusted locations for fabrication. With virtually no visibility into the manufacturing supply chain, it is nearly impossible for designers or program offices to know, with any level of confidence, if the integrated circuit (IC) chip has been compromised at a point in the manufacturing process. To address this challenge, post-silicon verification and validation techniques have been developed for assuring the equivalence of the manufactured design to the trusted golden design. Significant progress has been made over the years with digital design verification and validation, developing tools that scale to perform equivalence checks between the recovered and golden design across physical layout, function, logic, graph, and timing modalities. These techniques, however, do not map well into the analog domain, thus leaving a significant lack of tools, techniques, and approaches for assuring analog, mixed-signal, and radio frequency (RF) designs.

### BRIEF DESCRIPTION OF THE DRAWINGS

Reference should be made to the following detailed description which should be read in conjunction with the following figures, wherein like numerals represent like parts.

FIG. 1 illustrates a system for post-silicon analog design verification and validation consistent with the present disclosure.

FIG. 2A is an example of the steps for post-silicon digital design verification and validation, consistent with the present disclosure.

FIG. 2B is an example of the steps for post-silicon analog design verification and validation, consistent with the present disclosure.

FIG. 2C is an example flow diagram for post-silicon analog design verification and validation, consistent with the present disclosure.

FIG. 3A is an example illustrating a high confidence characterization of an IC, consistent with the present disclosure.

FIG. 3B is an example illustrating a low confidence characterization of an IC, consistent with the present disclosure.

FIG. 4 is an example of a flow diagram for an Analog, Mixed Signal, and Radio Frequency (AMS/RF) verification and validation framework, consistent with the present disclosure.

FIG. 5A is an example of a graph from a trusted golden design, consistent with the present disclosure.

FIG. 5B is an example of a graph from a recovered design, consistent with the present disclosure.

FIG. 6 is an example illustrating possible deviations when comparing two graphs consistent with the present disclosure.

FIG. 7 is an example of a test case of a recovered design, consistent with the present disclosure.

FIG. 8 is a flowchart diagram depicting operations for post-silicon analog design verification and validation consistent with the present disclosure.

### DETAILED DESCRIPTION

The central issue that differentiates analog verification and validation from digital verification and validation is in the way analog relates to different mathematical and physical phenomena. Consequently, sources of deviation in a design can expand beyond logical failures (e.g., changes in binary logic) to include performance changes (e.g., bandwidth alterations in a filter) and physics-related changes (e.g., the introduction of negative capacitance). A comprehensive solution would involve comparing electromagnetic (EM) field solutions of the golden design and the recovered design, within a specified tolerance range. Applying this method on a large scale with modern computation, however, is currently unfeasible.

Disclosed herein is a novel system and method to perform post-silicon verification and validation on analog, mixed-signal, and RF designs. The disclosed system and method introduces a novel approach to post-silicon analog verification and validation incorporating concepts across the analog, RF, power, and mixed-signal disciplines. These disciplines initiate their designs schematically before transitioning to a parasitic representation. Accordingly, the disclosed system first analyzes the recovered design schematically for topology and performance verification, then validates it at the parasitic level. Schematic level verification and validation quickly captures deviations in the electrical domain, whereas parasitic level verification and validation captures deviations in both the physical and electrical domains at the expense of computational complexity. In both cases, designs are represented as graphs and verification and validation processes are performed on these graph structures. By representing circuits as graphs, the disclosed system leverages the existing field of graph theory to inform circuit verification and validation.

The disclosed system was validated through application to a real-world fabricated analog design. The experiment ingested a fabricated 14 nm fin field-effect transistor (FinFET) Configurable Ring Oscillator (CRO) that contained implemented design deviations that were fabricated at the foundry but were not present in the golden Graphic Design System II (GDSII) layout. The deviations were able to elude the traditional functional, logical, and other equivalency checks used in digital verification and validation. However, the disclosed system for analog verification and validation identified and marked them for deeper analysis.

Analog circuit graph analysis requires netlists, both schematic level and parasitic. These netlists are extracted from both the recovered and golden layouts. In some embodiments, these netlists may be Simulation Program with Integrated Circuit Emphasis (SPICE) netlists. In the example embodiments that follow, SPICE netlists will be used for simplicity although in some other embodiments other netlists may be used. In some embodiments, existing tools may be used to extract the SPICE netlists from the recovered and golden layouts, for example, Cadence Pegasus for schematic netlists and Cadence Quantus for parasitic netlists, both from Cadence Design Systems, Inc., of San Jose, California. These netlists are converted to graph objects using a custom parser. In these circuit graphs, nodes represent either a net or an electrical device, while edges represent a connection between a net and a device component pin. Additional metadata about position and device parameters are embedded in the nodes. Through parametric graph isomorphism checks, deviations in circuit topology and component parameters can be quickly identified.

Parametric graph isomorphism, tailored to match nodes based on type and parameters such as position and electrical device parameters, serves as a revolutionary tool for detecting deviations between two analog designs. Parametric graph isomorphism creates a mapping between nodes representing capacitance, resistance, and inductance at specific geometric layout locations in the golden and recovered graphs, marking missing nodes or nodes outside a given tolerance as deviation candidates. Parameters can be mapped either exactly or through some tolerance, allowing some margin to account for process variations and imaging artifacts.

To overcome the complexity of parasitic graphs, computation time is reduced by using graph isomorphism on parasitic graphs through analog informed graph reduction techniques that preserve electrical relationships created by a physical layout. In some embodiments, Direct Current (DC) and Alternating Current (AC) graph reduction techniques may be used. DC simplification treats inductors as short circuits and capacitors as open connections. AC simplification treats resistors, capacitors, and inductors as complex impedances, combining them to create a graph similar to a schematic graph with complex impedances approximating parasitics. Running parametric graph isomorphism on both graphs provides further validation of a design versus a schematic level comparison alone in less compute time than on a full parasitic graph.

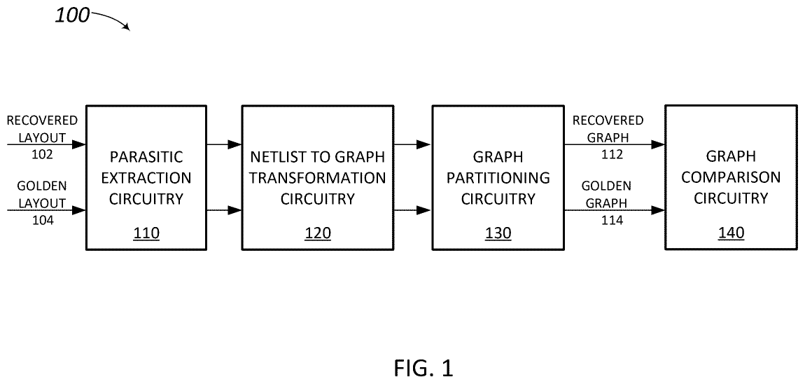

FIG. 1 illustrates a system 100 for post-silicon analog design verification and validation consistent with the present disclosure. In the example system 100, a recovered layout 102 and a golden layout 104 for a design are received by parasitic extraction circuitry 110. In an embodiment, delayering, imaging, and feature extraction techniques may be used to generate the recovered layout 102 from the device to be verified and validated. In other embodiments, any other techniques may be used to generate the recovered layout 102 as would be known to one skilled in the art. In some instances, the recovered layout 102 may include the full circuit design files across the design stack-up. In other instances, the recovered layout 102 may be a subset of the full circuit design files. Since analog circuit graph analysis requires netlists, both schematic level and parasitic, the parasitic extraction circuitry 110 extracts SPICE netlists from both the recovered layout 102 and the golden layout 104.

The SPICE netlists for both the recovered layout 102 and the golden layout 104 are then sent to the netlist to graph transformation circuitry 120, where a custom parser converts the SPICE netlists into circuit graphs. In these circuit graphs, nodes represent either a net or an electrical device, while edges represent a connection between a net and a device component pin. Additional metadata about position and device parameters may be embedded in the nodes.

In an embodiment, the parser may be a Python script that tokenizes the SPICE netlist. From the tokens that are generated, a graph is produced. In an embodiment, the graph may be in the GraphML format, which is an Extensible Markup Language (XML)-based file format for graphs. The system may perform this via normal parsing algorithms and practices as would be known to one skilled in the art. For example, the parser may read a SPICE netlist line by line, breaking apart each part of the line. The parser may create nodes whose names are the instance name found in the netlist. It may then embed any parameter data along with the model of the device in that node. The parser may also look at what connections are specified in the line of the netlist currently being parsed and turn those nets into edges in the graph.

To overcome the complexity of parasitic graphs, computation time is reduced by using graph isomorphism on parasitic graphs through analog informed graph reduction techniques that preserve electrical relationships created by a physical layout. Therefore, the graphs generated from the recovered layout 102 and the golden layout 104 are reduced by graph partitioning circuitry 130 to generate a recovered graph 112 and a golden graph 114.

The recovered graph 112 and the golden graph 114 are then sent to a graph comparison circuitry 140. The graph comparison circuitry 140 performs a comparison of the recovered graph 112 and the golden graph 114 to determine the greatest common subgraph between the two graphs. In an embodiment, parametric graph isomorphism is used to determine the greatest common subgraph between the two graphs. To determine the greatest common subgraph, the recovered graph 112 and the golden graph 114 are traversed to obtain a subgraph that is common between them. The subgraph is then continuously expanded until the largest subgraph is found. The algorithm may use the metadata of the nodes in the graphs (e.g., R value (the resistance value of a resistor), or Length and Width, etc.) to determine whether a node is “common” (shared) by the two input graphs, along with the edge connectivity of the nodes (e.g., does a node A in the recovered graph have 2 edges like a node B in the golden graph).

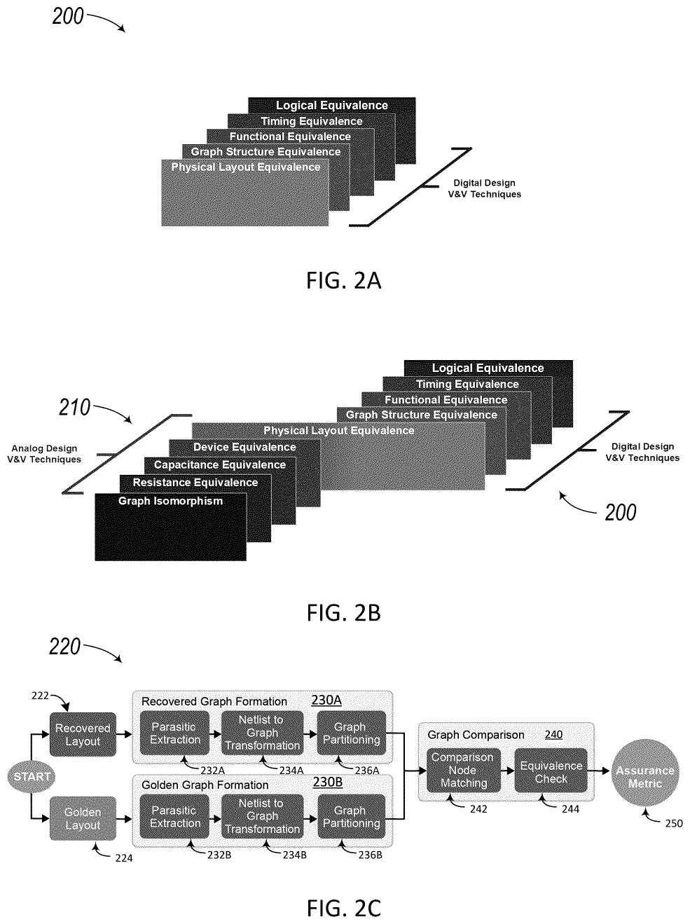

FIG. 2A is one illustrative example of existing solutions for digital design verification and validation.

FIG. 2B is an example block diagram 210 for post-silicon analog design verification and validation compared to the block diagram 200 for post-silicon digital design verification and validation of FIG. 2A. The example block diagram 210 of FIG. 2B illustrates the steps for post-silicon analog design verification and validation.

The example block diagram 210 of FIG. 2B illustrates the specific improvements and new art showing how analog design verification and validation techniques are an “expansion” beyond digital, however, there is some overlap with the digital techniques. The additional techniques and developed algorithms and processes that enable analog design verification and validation are disclosed herein.

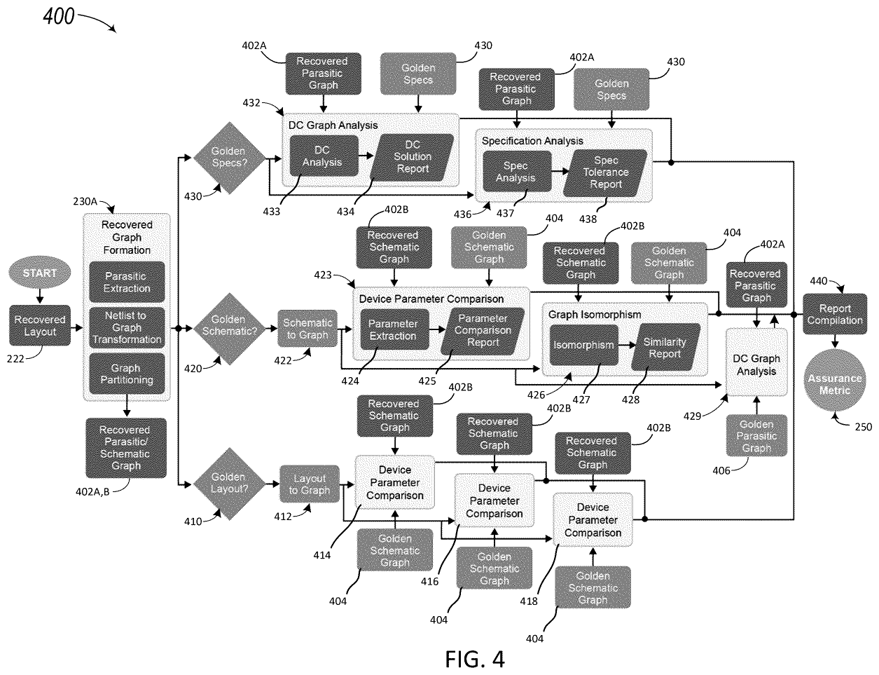

FIG. 2C is an illustrative example flow diagram 220 for post-silicon analog design verification and validation, consistent with the present disclosure. A more detailed flow diagram of the AMS/RF (Analog, Mixed Signal, and Radio Frequency) framework may be found in FIG. 4. In the illustrative example of FIG. 2C, a recovered layout 222 is received by a recovered graph formation 230A, and a golden layout 224 is received by a golden graph formation 230B. The recovered layout 222 and the golden layout 224 may be, for example, the recovered layout 102 and the golden layout 104 from FIG. 1, respectively. The recovered graph formation 230A includes a parasitic extraction 232A, a netlist to graph transformation 234A, and a graph partitioning 236A. The recovered graph formation 230A, the parasitic extraction 232A, the netlist to graph transformation 234A, and the graph partitioning 236A may be performed by the parasitic extraction circuitry 110, the netlist to graph transformation circuitry 120, and the graph partitioning circuitry 130, respectively, from FIG. 1. Details of these steps can be found in the description of FIG. 1 above.

Golden graph formation 230B includes a parasitic extraction 232B, a netlist to graph transformation 234B, and a graph partitioning 236B. The golden graph formation 230B, the parasitic extraction 232B, the netlist to graph transformation 234B, and the graph partitioning 236B may be performed by the parasitic extraction circuitry 110, the netlist to graph transformation circuitry 120, and the graph partitioning circuitry 130, respectively, from FIG. 1. Details of these steps can be found in the description of FIG. 1 above.

The resulting graphs created by the recovered graph formation 230A and the golden graph formation 230B are received by a graph comparison 240. The graph comparison 240 include a comparison node matching 242 and an equivalence check 244. The results of the comparison node matching 242 and the equivalence check 244 may be used to generate the assurance metric 250. Details of these steps can be found in the description of FIG. 1 above.

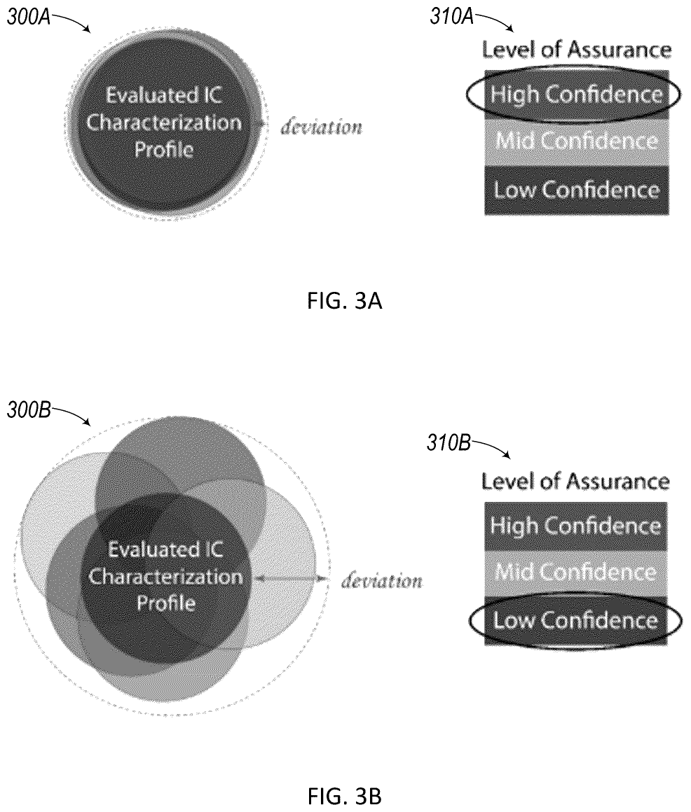

FIG. 3A is an example illustrating a high confidence characterization of an IC, and FIG. 3B is an example illustrating a low confidence characterization of an IC, consistent with the present disclosure. In order to ensure that a design has not been changed, it is not enough to just look at the layout of a design. Therefore, the disclosed system and method verifies multiple modalities of the design. As used herein, modalities may include, but are not limited to, functional performance, logical equivalence, behavior across voltage, temperature, and process variation (note process variation in this context refers to the variation that the foundry introduces to the IC due to a non-ideal manufacturing process), timing behavior of various signal lines in the IC, graph topology, schematic layout, GDS layout, radiation output and response to radiation, and material properties such as substrate doping, etc., Note that as used herein, “characterized” means that the modality is known to the system, not that the system has solved that issue.

Some modalities may indicate that a design has been changed, while other modalities might indicate that the design was unchanged. In the example of FIG. 3A, graph 300A shows a characterization profile for an evaluated IC. As can be seen in graph 300A, the deviation between the various modalities of the evaluation have a uniform overlap between the expected profile and the evaluated profile. Therefore, based on the evaluation of the IC, the level of assurance 310A for this IC has a high confidence that the IC does not deviate from the original design.

In the graph 300B, however, the characterization profile for the evaluated IC show a non-uniform overlap between the expected profile and the evaluated profile. Therefore, based on the evaluation of the IC, the level of assurance 310B for this IC has a low confidence, indicating that there are deviations between the IC that was evaluated and the original design.

FIG. 4 is an example of a flow diagram 400 for an AMS/RF verification and validation assurance framework, consistent with the present disclosure. The example of FIG. 4 is consistent with the example of FIG. 2C, but includes more details of the flow, as well as alternative flows depending on the available data for the golden design. FIG. 2C only shows the flow if only the layout of a design is available. FIG. 4 considers the cases where a layout may not be available, but a schematic or specifications of the design is available. Each input type changes how the disclosed system performs the analysis and what the result of the analysis means. It should be noted, however, that in the flow 400 of FIG. 4 any combination of the layout, the schematic, and/or the specifications of the design may be used in the verification and validation.

As in FIG. 2C, the flow diagram 400 receives the recovered layout 222 in recovered graph formation 230A to generate a recovered parasitic graph 402A and/or a schematic graph 402B. The recovered schematic graph 402B is the same as the recovered parasitic graph 402A, but without parasitics. Typically, the recovered schematic graph 402B is much smaller than the recovered parasitic graph 402A. In an embodiment, the disclosed system compares like graphs, so a schematic graph is compared against other schematic graphs and is not compared to a parasitic graph. Likewise, a parasitic graph is compared to other parasitic graphs. Comparing a schematic graph to a parasitic graph would not progress towards an assurance assessment due to, for example, the sheer number of false positives such a comparison would generate. The flow diagram 400, however, has different paths based on the data available for the golden design.

If, as in the example of FIG. 2C, a golden layout 410 is available, then the path is similar to the path described in FIG. 2C. First, a layout to graph 412 converts the golden layout 410 to a golden schematic graph 404. In a device parameter comparison 414, a device parameter comparison 416, and a device parameter comparison 418, the recovered schematic graph 402B is compared to the golden schematic graph 404. In some embodiments, the system may generate different versions of the recovered schematic graph 402B and/or the golden schematic graph 404 and process them in parallel, for example, based on different techniques for graph reduction in the graph partitioning block of recovered graph formation 230A that may generate multiple versions the recovered schematic graph 402B and/or the golden schematic graph 404. The processing of the different versions of the recovered schematic graph 402B and/or the golden schematic graph 404 are shown by the separate device parameter comparison blocks 414, 416, and 418. In an embodiment, any number of device parameter comparison blocks may be processed in parallel. This may reduce the overall time for the processing, rather than processing different versions serially.

If a golden schematic 420 is available, then the golden schematic 420 is converted into a golden schematic graph 404 and a golden parasitic graph 406 by a schematic to graph 422. The resulting golden schematic graph 404 and the recovered schematic graph 402B are received by a device parameter comparison 423. A parameter extraction 424 performs the comparison of the recovered schematic graph 402B to the golden schematic graph 404, and the device parameter comparison 423 then generates a parameter comparison report 425. The parameter comparison report 425 may then be passed to the report compilation 440.

The recovered schematic graph 402B and the golden schematic graph 404 are also received by a graph isomorphism 426. In the graph isomorphism 426, isomorphism 427 compares the recovered schematic graph 402B and the golden schematic graph 404 and generates a similarity report 428. The similarity report 428 may then be passed to the report compilation 440.

The recovered parasitic graph 402A and a golden parasitic graph 406 are also received by a DC graph analysis 429. The results of the DC graph analysis 429 may be passed on the report compilation 440 and may be incorporated into the assurance metric 250.

In some instances, the system may use both the device parameter comparison 423 and the graph isomorphism 426 to perform the verification and validation. In these instances, both the parameter comparison report 425 and the similarity report 428 may be used to create the assurance metric 250. In some other instances, the system may use either the device parameter comparison 423 or the graph isomorphism 426 to perform the verification and validation.

If a golden specifications 430 is available, then the golden specifications 430 and the recovered parasitic graph 402A may be received by a DC graph analysis 432. The DC graph analysis 432 includes a DC analysis 433, which performs the comparison of the recovered parasitic graph 402A and the golden specifications 430. The DC graph analysis 432 then generates a DC solution report 434 based on the results of the comparison. The DC solution report 434 is then forwarded to the report compilation 440. The DC solution report 434 may then be incorporated into the assurance metric 250.

The golden specifications 430 and the recovered parasitic graph 402A may also be received by a specifications analysis 436. The specifications analysis 436 includes a spec analysis 437, which performs the analysis of the recovered parasitic graph 402A and the golden specifications 430. The specifications analysis 436 then generates a specifications tolerance report 438 based on the results of the comparison. The specifications tolerance report 438 is then forwarded to the report compilation 440. The specifications tolerance report 438 may then be incorporated into the assurance metric 250.

In some instances, the system may use both the DC graph analysis 432 and the specifications analysis 436 to perform the verification and validation. In these instances, both the DC solution report 434 and the specifications tolerance report 438 may be used to create the assurance metric 250. In some other instances, the system may use either the DC graph analysis 432 or the specifications analysis 436 to perform the verification and validation.

In some embodiments, at least one of a golden layout 410, a golden schematic 420, or a golden specifications 430 may be available for the system to use for post-silicon analog design verification and validation. If only one of the golden layout 410, the golden schematic 420, or the golden specifications 430 is available, then the system will use the available golden source for the verification and validation. If, however, more than one golden source is available, the system may use any one golden source or any combination of the available golden sources, which may include all the available golden sources. In some instances, using more than one golden source may increase the accuracy of the verification and validation, while in some other instances, the choice among multiple available golden references may depend on the objective of the particular analysis. In the instances where more than one golden source is used, the report compilation 440 may compile any or all of the reports from each module, and the assurance metric 250 may be determined based on the compiled report.

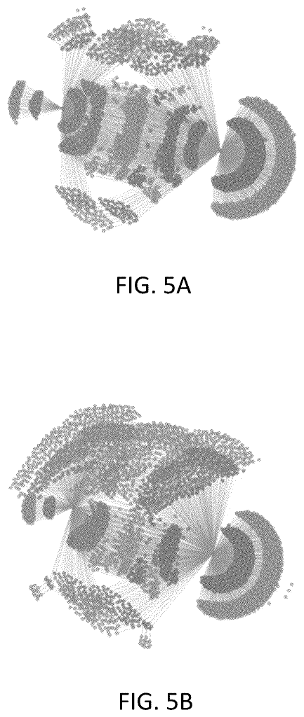

FIG. 5A is an example of a graph from a trusted golden design, and FIG. 5B is an example of a graph from a recovered design which is purported to be an IC of the trusted golden design, but which actually has one or more deviations embedded within it. As can be seen in FIG. 5A, even for a “simple” design, the resulting graph can be very complex and visually difficult to distinguish from the graph of the recovered design with one or more embedded deviations as shown in 5B.

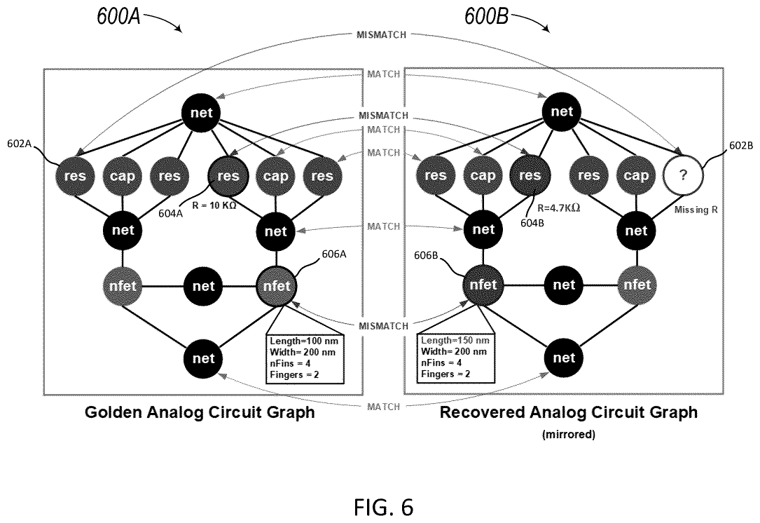

FIG. 6 is an example illustrating possible deviations when comparing two graphs, a golden analog circuit graph 600A and a recovered analog circuit graph 600B. It should be noted that the recovered analog circuit graph 600B is mirrored from the golden analog circuit graph 600A. The example deviations in FIG. 6 convey some of the various ways in which a graph can deviate. The recovered analog circuit graph 600B could have, but is not limited to having, missing nodes, additional nodes, nodes with mismatching parameters, additional parameters, or even missing parameters.

For example, the golden analog circuit graph 600A contains resistor 602A, while the resistor that should be in the corresponding location 602B in the recovered analog circuit graph 600B is missing. The golden analog circuit graph 600A contains resistor 604A which has a resistance value of 10 kiloohms (kΩ), while the recovered analog circuit graph 600B has a resistor at that location with a resistance value of 4.7 kΩ. The final example of FIG. 6 is a transistor 606A of the golden analog circuit graph 600A which has a length of 100 nanometers (nm), while the corresponding transistor 606B of the recovered analog circuit graph 600B has a length of 150 nm.

It should be noted that although the example of FIG. 6 illustrates three possible deviations between the golden analog circuit graph 600A and the recovered analog circuit graph 600B, many other types and numbers of deviations may be found between two graphs, as would be known to one skilled in the art.

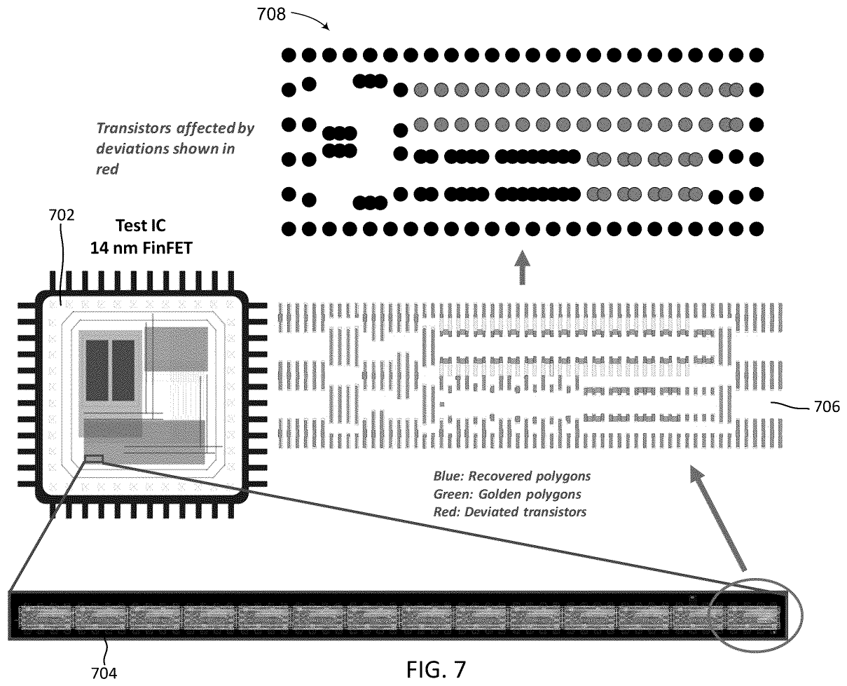

FIG. 7 represents the actual results of a test case of a recovered design. The design for this test case was an IC 702 built on a 14 nm FinFET process that was fabricated by a foundry. The IC 702 was analyzed by the disclosed system against a golden design for deviations in the analog circuitry. For this test, the IC 702 was delayered, pictures 704 were taken of the individual layers, and, from those pictures, graphs 706 were created which were analyzed by the disclosed system. One stage of a ring oscillator is shown in image 708 with the non-affected transistors shown in black and the transistors affected due to the introduced deviations shown in red. The disclosed system correctly identified that the design was changed and where the changes were made.

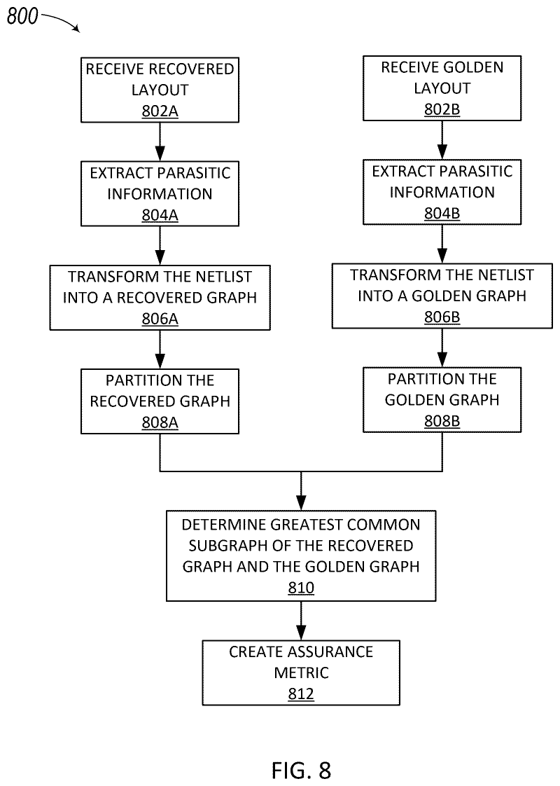

FIG. 8 is a flowchart diagram of workflow 800 depicting operations for post-silicon analog design verification and validation consistent with the present disclosure. It should be appreciated that embodiments of the present disclosure provide at least for post-silicon analog design verification and validation. However, FIG. 8 provides only an illustration of one implementation and does not imply any limitations with regard to the environments in which different embodiments may be implemented. Many modifications to the depicted environment may be made by those skilled in the art without departing from the scope of the disclosure as recited by the claims.

Receive recovered layout and golden data (operations 802A and 802B). In the illustrated example embodiment, a recovered layout (operation 802A) and a golden data (operation 802B) are received. In an embodiment, the golden data may include at least one of a golden layout, a golden netlist, and a golden schematic. The recovered layout and the golden data may be incomplete, especially in the case of the recovered layout.

Extract parasitic information (operations 804A and 804B). In these operations, a recovered netlist is built for the recovered layout (operation 804A) and a golden netlist is built for the golden layout (operation 804B). These SPICE netlists contain information about elements within a design that are considered “undesirable,” i.e., parasitics. In some embodiments, a tool such as Cadence Quantus may be used to extract the parasitic netlists. In an embodiment, this process may not consider all types of true parasitics. The tool or algorithm that performs this operation only considers certain kinds of parasitics that typically are considered “dominant” with designs.

Transform the netlist into a graph (operations 806A and 806B). In these operations, the SPICE netlists for the recovered layout (operation 806A) and the golden layout (operation 806B) are converted into graphs. In an embodiment, this is primarily a format conversion from the SPICE netlist into the graph. The graph format is necessary for the comparison algorithm in operation 810.

Partition the graph (operations 808A and 808B). Operations 808A (recovered graph) and 808B (golden graph) are complexity reduction steps. In an embodiment, the exact choice of how to reduce the complexity of the graph is particular to, and inexact for, the given design.

For example, a graph reduction may be a DC simplification where all capacitors are considered as open circuits and all inductors are re considered as short circuits. This DC simplification may be easier to process, but this might discard the wrong devices that need to be inspected. Another example graph reduction might discard any resistor, inductor, and capacitor devices below a given value. This is technically easier to process, although the reduction in processing time may be small. If a greater reduction is desired, i.e., discard more values, then the graph nodes may be organized in a similar way as the layout of the design and pieces deemed unimportant may be discarded. Some nodes in the graph may be converted to a different form (i.e., capacitor and inductor converted to resistor based on a given frequency). It should be noted that these are some examples of possible graph reductions to reduce the computational complexity and are not exhaustive. Many other graph reduction techniques may be employed.

Determine greatest common subgraph of the recovered graph and the golden graph (operation 810). In this operation, the two graphs are traversed to obtain a subgraph between the recovered graph and the golden graph that is common between them. Then the subgraph is continuously expanded until the largest subgraph is found. The algorithm may use the metadata of the nodes in the graphs (e.g., R value, or Length and Width, etc.) to determine whether a node is “common” (shared) by the two input graphs, along with the edge connectivity of the nodes (e.g., does a node A in the recovered graph have 2 edges like a node B in the golden graph).

Create assurance metric (operation 812). In an embodiment, the assurance metric may be a heatmap that colors areas of the design where the located differences between the graphs are placed. For example, if there is an extra node in the recovered graph, the location metadata of that node may be used to show on the heatmap where that node is located. The “metric” is the clustering of deviations via the heatmap for ease of location.

In some embodiments, the assurance metric may be, but is not limited to, a confidence score (e.g., 95% confident that the recovered design matches the golden design), or a report sheet that lists the location plus the suspected impact, i.e., the parameter that was changed or what part was affected. In some other embodiments, any other assurance metric may be used as would be known to one skilled in the art.

As used in this application and in the claims, a list of items joined by the term “and/or” can mean any combination of the listed items. For example, the phrase “A, B and/or C” can mean A; B; C; A and B; A and C; B and C; or A, B, and C. As used in this application and in the claims, a list of items joined by the term “at least one of” can mean any combination of the listed terms. For example, the phrases “at least one of A, B or C” can mean A; B; C; A and B; A and C; B and C; or A, B and C.

The term “coupled” as used herein refers to any connection, coupling, link, or the like by which signals carried by one system element are imparted to the “coupled” element. Such “coupled” devices, or signals and devices, are not necessarily directly connected to one another and may be separated by intermediate components or devices that may manipulate or modify such signals.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems. Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

Any of the operations described herein may be implemented in a system that includes one or more non-transitory storage devices having stored therein, individually or in combination, machine-readable instructions that when executed by circuitry perform the operations. “Circuitry”, as used in any embodiment herein, may comprise, for example, singly or in any combination, hardwired circuitry, programmable circuitry such as processors comprising one or more individual instruction processing cores, state machine circuitry, and/or firmware that stores instructions executed by programmable circuitry and/or future computing circuitry including, for example, massive parallelism, analog or quantum computing, hardware embodiments of accelerators such as neural net processors and non-silicon implementations of the above. The circuitry may, collectively or individually, be embodied as circuitry that forms part of a larger system, for example, an integrated circuit (IC), system on-chip (SoC), application-specific integrated circuit (ASIC), programmable logic devices (PLD), digital signal processors (DSP), field programmable gate array (FPGA), logic gates, registers, semiconductor device, chips, microchips, chip sets, etc.

The non-transitory storage device includes any type of tangible medium, for example, any type of disk including hard disks, floppy disks, optical disks, compact disk read-only memories (CD-ROMs), compact disk rewritables (CD-RWs), and magneto-optical disks, semiconductor devices such as read-only memories (ROMs), random access memories (RAMs) such as dynamic and static RAMs, erasable programmable read-only memories (EPROMs), electrically erasable programmable read-only memories (EEPROMs), flash memories, Solid State Disks (SSDs), embedded multimedia cards (eMMCs), secure digital input/output (SDIO) cards, magnetic or optical cards, or any type of media suitable for storing electronic instructions. Other embodiments may be implemented as software executed by a programmable control device. Also, it is intended that operations described herein may be distributed across a plurality of physical devices, such as processing structures at more than one different physical location.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

Reference throughout this specification to “one embodiment” or “an embodiment” means that a particular feature, structure, or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

What is claimed is:

1. A method for post-silicon analog design verification and validation, the method comprising:
receiving a recovered layout and a golden data for a design;
extracting a recovered netlist from the recovered layout and a golden netlist from the golden data;
converting the recovered netlist into a recovered graph and the golden netlist into a golden graph;
partitioning the recovered graph and the golden graph; and
determining an assurance metric by comparing the recovered graph and the golden graph.

2. The method of claim 1, wherein the golden data may include at least one of a layout, a schematic, and a specifications.

3. The method of claim 1, wherein extracting the recovered netlist from the recovered layout and the golden netlist from the golden data further comprises:
extracting a recovered parasitic graph from the recovered layout and a golden parasitic graph from the golden data.

4. The method of claim 1, wherein determining the assurance metric by comparing the recovered graph and the golden graph further comprises:
determining a greatest common subgraph of the recovered graph and the golden graph.

5. The method of claim 4, wherein parametric graph isomorphism is used to determine the greatest common subgraph between the recovered graph and the golden graph.

6. The method of claim 4, wherein determining the greatest common subgraph of the recovered graph and the golden graph further comprises:
traversing the recovered graph and the golden graph to obtain a common subgraph between the recovered graph and the golden graph; and
expanding the common subgraph continuously until the greatest common subgraph between the recovered graph and the golden graph is determined.

7. The method of claim 1, wherein the assurance metric includes at least one of a heatmap that colors areas of the design where any located differences between the recovered graph and the golden graph are located, a confidence score, and a report sheet that lists a location plus a suspected impact for each difference between the recovered graph and the golden graph.

8. A non-transitory storage device that includes machine-readable instructions that, when executed by one or more processors, cause one or more processors to perform operations, comprising:
receiving a recovered layout and a golden data for a design;
extracting a recovered netlist from the recovered layout and a golden netlist from the golden data;
converting the recovered netlist into a recovered graph and the golden netlist into a golden graph;
partitioning the recovered graph and the golden graph; and
determining an assurance metric by comparing the recovered graph and the golden graph.

9. The non-transitory storage device of claim 8, wherein the golden data may include at least one of a layout, a schematic, and a specifications.

10. The non-transitory storage device of claim 8, wherein extracting the recovered netlist from the recovered layout and the golden netlist from the golden data further comprises:
extracting a recovered parasitic graph from the recovered layout and a golden parasitic graph from the golden data.

11. The non-transitory storage device of claim 8, wherein determining the assurance metric by comparing the recovered graph and the golden graph further comprises:
determining a greatest common subgraph of the recovered graph and the golden graph.

12. The non-transitory storage device of claim 11, wherein parametric graph isomorphism is used to determine the greatest common subgraph between the recovered graph and the golden graph.

13. The non-transitory storage device of claim 11, wherein determining the greatest common subgraph of the recovered graph and the golden graph further comprises:
traversing the recovered graph and the golden graph to obtain a common subgraph between the recovered graph and the golden graph; and
expanding the common subgraph continuously until the greatest common subgraph between the recovered graph and the golden graph is determined.

14. The non-transitory storage device of claim 8, wherein the assurance metric includes at least one of a heatmap that colors areas of the design where any located differences between the recovered graph and the golden graph are located, a confidence score, and a report sheet that lists a location plus a suspected impact for each difference between the recovered graph and the golden graph.

15. A system for post-silicon analog design verification and validation, the system comprising:
parasitic extraction circuitry to extract a recovered netlist from a recovered layout and a golden netlist from a golden data for a received design;
netlist to graph transformation circuitry to convert the recovered netlist into a recovered graph and the golden netlist into a golden graph;
graph partitioning circuitry to partition the recovered graph and the golden graph; and
graph comparison circuitry to determine an assurance metric by comparing the recovered graph and the golden graph.

16. The system of claim 15, wherein the graph partitioning circuitry partitions the recovered graph and the golden graph to reduce a computation time.

17. The system of claim 15, wherein the parasitic extraction circuitry also to extract a recovered parasitic graph from the recovered layout and a golden parasitic graph from the golden data.

18. The system of claim 15, wherein the graph comparison circuitry also to determine a greatest common subgraph of the recovered graph and the golden graph.

19. The system of claim 18, wherein the graph comparison circuitry also to:
traverse the recovered graph and the golden graph to obtain a common subgraph between the recovered graph and the golden graph; and
expand the common subgraph continuously until the greatest common subgraph between the recovered graph and the golden graph is determined.

20. The system of claim 15, wherein the assurance metric includes at least one of a heatmap that colors areas of the received design where any located differences between the recovered graph and the golden graph are located, a confidence score, and a report sheet that lists a location plus a suspected impact for each difference between the recovered graph and the golden graph.
